(19) United States
(12) Patent Application Publication
(10) Pub. No.: US 2015/0129833 A1
(43) Pub. Date: May 14, 2015

(54) LIGHT EMITTING DEVICE PACKAGE

(71) Applicants: Mi Jeong YUN, Suwon-si (KR); Joong Kon SON, Seoul (KR); Yoichi KUROKAWA, Yongin-si (KR); Kyung Wook HWANG, Hwaseong-si (KR)

(72) Inventors: Mi Jeong YUN, Suwon-si (KR); Joong Kon SON, Seoul (KR); Yoichi KUROKAWA, Yongin-si (KR); Kyung Wook HWANG, Hwaseong-si (KR)

(21) Appl. No.: 14/454,498

(22) Filed: Aug. 7, 2014

(30) Foreign Application Priority Data
Nov. 8, 2013 (KR) 10-2013-0135722

(51) Int. Cl. H01L 33/06; H01L 33/58; H01L 33/24

(52) U.S. Cl. CPC H01L 33/06; H01L 33/24; H01L 33/58
USPC 257/13

(57) ABSTRACT

A light emitting device package includes a package substrate, a light emitting device, a resin portion and a light scattering agent. The light emitting device is disposed on the package substrate and includes a plurality of light emitting nanostructures. The resin portion is disposed on the package substrate and seals the light emitting device. The light scattering agent is dispersed in the resin portion and includes a material having a refractive index greater than a refractive index of a material forming the resin portion.

### CROSS-REFERENCE TO RELATED APPLICATION

This application claims priority to, and benefit of Korean Patent Application No. 10-2013-0135722, filed on Nov. 8, 2013, with the Korean Intellectual Property Office, the entire disclosure of which is incorporated herein by reference.

### TECHNICAL FIELD

The present disclosure relates to a light emitting device package.

### BACKGROUND

Semiconductor light emitting devices emit light through the recombination of electrons and holes when a current flows therethrough, and are commonly used as light sources due to various advantages thereof such as low power consumption, high levels of luminance, compactness, and the like. In particular, with the development of nitride light emitting devices, usage thereof has been greatly expanded and nitride light emitting devices are employed as light sources in backlight units used for displays, general illumination devices, electric systems for vehicles, and the like. Accordingly, various attempts are being made to improve properties of light emitting device packages using semiconductor light emitting devices, and in particular, there has been demand for the development of light emitting device packages for improving luminous efficiency.

### SUMMARY

An embodiment of the present inventive concept may provide a light emitting device package, employing a light emitting device having light emitting nanostructures, for improving light extraction efficiency of the light emitting device package.

One aspect of the present disclosure relates to a light emitting device package including a package substrate, a light emitting device, a resin portion and a light scattering agent. The light emitting device is disposed on the package substrate and including a plurality of light emitting nanostructures. The resin portion is disposed on the package substrate and seals the light emitting device. The light scattering agent is dispersed in the resin portion and includes a material having a refractive index greater than a refractive index of a material forming the resin portion.

The light scattering agent may be a material selected from the group consisting of Al₂O₃, TiO₂, and combinations thereof.

A weight ratio of the light scattering agent to the resin portion may be in the range of 1% to 50%.

Blue light, red light, green light, or white light may be emitted by the light emitting device, and the resin portion may not include light wavelength converting materials.

Light emitted by the light emitting device may have a maximum luminescence intensity at an angle of at least 40° with respect to a direction perpendicular with a surface on which the light emitting device is disposed.

The light emitting device may include a base layer including a first conductivity-type semiconductor material, an insulating layer disposed on the base layer and having a plurality of openings through which regions of the base layer are exposed, and a plurality of light emitting nanostructures disposed on each of the exposed regions of the base layer and including a nanocore. of the nanocore may include a first conductivity-type semiconductor material, an active layer, and a second conductivity-type semiconductor layer, sequentially disposed on side planes of the nanocore.

The light emitting nanostructures may have at least one of a polygonal pillar shape and a pyramidal shape.

The light emitting device package may further include a plurality of protruding portions having at least one of a cone shape and a dome shape, disposed on an upper surface of the resin portion.

The plurality of protruding portions may have cone shapes, and a range of an acute angle between a base plane and a side plane of the cone shape may be from (90°−θ_{c})−20° to (90°−θ_{c})+20°, where θc is a critical angle in which light emitted by the light emitting device passes through the resin portions and is entirely reflected internally without being emitted externally.

A range of the acute angle between the base plane and the side plane of the cone shape may be from 28.2° to 68.2°.

The plurality of protruding portions may have dome shapes and an aspect ratio of the dome shape may be greater than 0.5.

The package substrate may include first and second lead frames, and at least one of the first and second lead frames may include a plurality of protruding portions disposed on an upper surface thereof.

The plurality of protruding portions may have at least one of a cone shape and a dome shape.

The plurality of protruding portions may have cone shapes, and a range of an acute angle between a base plane and a side plane of the cone shape may be 50° or less.

The range of acute angle between the base plane and the side plane of the cone shape may be from 20° to 40°.

Another aspect of the present disclosure encompasses a light emitting device package may including a package substrate, a light emitting device, a resin portion and a plurality of protruding portions. The light emitting device is disposed on the package substrate and includes a plurality of light emitting nanostructures. The resin portion is disposed on the package substrate and seals the light emitting device. The plurality of protruding portions have at least one of a cone shape and a dome shape and are disposed on an upper surface of the resin portion.

The plurality of protruding portions may have a cone shape, and a range of an acute angle between a base plane and a side plane of the cone shape may be from (90°−θc)−20° to (90°−θc)+20°, where θc is a critical angle in which light emitted by the light emitting device passes through the resin portions and is entirely reflected internally without being emitted externally.

A range of the acute angle between the base plane and the side plane of the cone shape may be from 28.2° to 68.2°.

The plurality of protruding portions may have dome shapes, and the aspect ratio of the dome shapes may be greater than 0.5.

The package substrate may include first and second lead frames, and at least one of the first and second lead frames may include a plurality of protruding portions disposed on an upper surface thereof.

The light emitting device package may further include a light scattering agent dispersed in the resin portion and including a material having a refractive index greater than that of a material forming the resin portion.

Still another aspect of the present disclosure relates to a light emitting device package including a package substrate, a light emitting device, and a resin portion. The package substrate includes first and second lead frames. The light emitting device is disposed on the package substrate, including a plurality of light emitting nanostructures. The resin portion is disposed on the package substrate and seals the light emitting device. At least one of the first and second lead frames includes a plurality of protruding portions disposed on an upper surface thereof.

The plurality of protruding portions may have at least one of a cone shape and a dome shape.

The plurality of protruding portions may have a cone shape, and a range of an acute angle between a base plane and a side plane of the cone shape may be 50° or less.

The range of the acute angle between the base plane and the side plane of the cone shape may be from 20° to 40°.

A bulb-type lamp may include the above-described light emitting device package, a light emitting module, a heat sink plate, and a cover unit. The light emitting module may include a circuit board such that the light emitting device package is disposed on the circuit board. The light emitting module having the light emitting device package disposed thereon is in direct contact with the heat sink plate. The cover unit may be disposed on the light emitting module.

### BRIEF DESCRIPTION OF DRAWINGS

The above and other aspects, features and other advantages of the present disclosure will be more clearly understood from the following detailed description taken in conjunction with the accompanying drawings, in which like reference characters may refer to the same or similar parts throughout the different views. The drawings are not necessarily to scale, emphasis instead being placed upon illustrating the principles of the embodiments of the present inventive concept. In the drawings, the thickness of layers and regions may be exaggerated for clarity.

FIG. 1 is a schematic cross-sectional view illustrating a light emitting device package according to an exemplary embodiment of the present inventive concept.

FIGS. 2A and 2B are schematic cross-sectional views illustrating examples of a light emitting device employed in a light emitting device package according to an exemplary embodiment of the present inventive concept.

FIGS. 3A and 3B are graphs illustrating photometric properties of a light emitting device according to an exemplary embodiment of the present inventive concept.

FIG. 4 is a graph of experimental results illustrating a relationship between a density of light scattering agent and light extraction efficiency.

FIGS. 5A and 5B are graphs comparing orientation angle properties of a light emitting device package according to an exemplary embodiment of the present inventive concept and a light emitting device package in which a light scattering agent is not included.

FIG. 6 is a schematic cross-sectional view illustrating a light emitting device package according to another exemplary embodiment of the present inventive concept.

FIG. 7 is a schematic cross-sectional view illustrating a light emitting device package according to another exemplary embodiment modified from the embodiment of FIG. 6.

FIGS. 8A and 8B are perspective views schematically illustrating light emitting device packages according to another exemplary embodiment of the present inventive concept.

FIGS. 9A and 9B are schematic plan views viewed from the top of light emitting device packages according to an exemplary embodiment of FIGS. 8A and 8B.

FIGS. 10A and 10B are graphs illustrating a relationship between light extraction efficiencies according to a change in shape of protruding portions of light emitting device packages according to an exemplary embodiment of FIGS. 8A and 8B, respectively.

FIG. 11 is a schematic cross-sectional view illustrating a light emitting device package according to another exemplary embodiment of the present inventive concept.

FIG. 12 is a schematic cross-sectional view illustrating a light emitting device package according to another exemplary embodiment of the present inventive concept.

FIG. 13 is a graph illustrating a relationship between light extraction efficiencies according to a change in shape of protruding portions of light emitting device packages according to an exemplary embodiment of FIG. 12.

FIG. 14 is a schematic cross-sectional view illustrating a light emitting device package modified from a light emitting device package according to an exemplary embodiment of FIG. 12.

FIG. 15 is a schematic cross-sectional view illustrating a light emitting device package according to another exemplary embodiment of the present inventive concept.

FIGS. 16 and 17 are exploded perspective views illustrating examples of a lighting device to which a light emitting device package according to an embodiment of the present inventive concept is applied.

FIGS. 18 and 19 illustrate examples of a backlight unit to which a light emitting device package according to an embodiment of the present inventive concept is applied.

FIG. 20 illustrates an example of a headlamp to which a light emitting device package according to an embodiment of the present inventive concept is applied.

### DETAILED DESCRIPTION

Exemplary embodiments of the present inventive concept will now be described in detail with reference to the accompanying drawings.

The disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

In addition, in this specification, terms such as ‘upper’, ‘upper portion’, ‘upper surface’, ‘lower’, ‘lower portion’, ‘lower surface’, or ‘side plane’ are designated based on the figures, and the designation of the terms may be changed according to the direction at which a light emitting device or a light emitting device package is disposed.

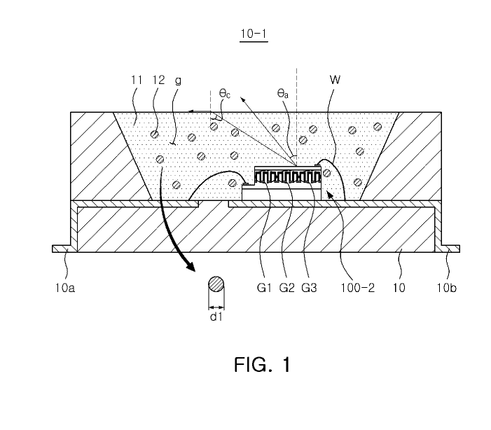

FIG. 1 is a schematic cross-sectional view illustrating a light emitting device package 10-1 according to an exemplary embodiment of the present inventive concept.

Referring to FIG. 1, a light emitting device package 10-1 according to an exemplary embodiment of the present inventive concept may include a package substrate 10, a light emitting device 100-2 mounted on the package substrate 10, and a resin portion disposed on the package substrate and sealing the light emitting device.

The package substrate 10 may be provided as a substrate on which the light emitting device 100-2 is mounted, and, according to an exemplary embodiment of the present inventive concept, the package substrate 10 may include a cavity g accommodating the light emitting device 100-2. The package substrate 10 may be molded with an opaque resin or a resin having a high degree of reflectivity, and may be formed of a polymer resin of which injection molding process may be easily performed. However, the present inventive concept is not limited thereto, and the package substrate 10 may be formed of various non-conductive materials such as ceramics, and the like. In this case, heat may be effectively dissipated. In addition, the package substrate 10 may be a printed circuit board (PCB) on which wiring patterns are formed.

In an exemplary embodiment of the present inventive concept, the package substrate 10 may include a pair of lead frames 10a and 10b electrically connected to the light emitting device 100-2 to apply actuating power to the light emitting device 100-2. The pair of lead frames 10a and 10b may be electrically connected to the light emitting device 100-2 through a conductive wire w and may be used as terminals for applying an external electric signal. The lead frames 10a and 10b may be formed of metallic materials having a high degree of electrical conductivity.

The resin portion 11 formed on the package substrate 10 may be used to seal the light emitting device and may be formed of a material selected from epoxy, silicon, modified silicon, urethane resin, oxetane resin, acrylic, polycarbonate, polyimide, or combinations thereof.

The light emitting device 100-2 may be employed as a light source in the light emitting device package 10-1 and may be a semiconductor light emitting device 100-2 including a plurality of light emitting nanostructures. The light emitting device 100-2 according to an embodiment of the present inventive concept may include active layers having a protruding structure, whereby light emitted by the light emitting device 100-2 may have a maximum luminescence intensity in a planar direction or at an angle of at least 40° with respect to a direction perpendicular of the plane on which the light emitting devices 100-2 are mounted.

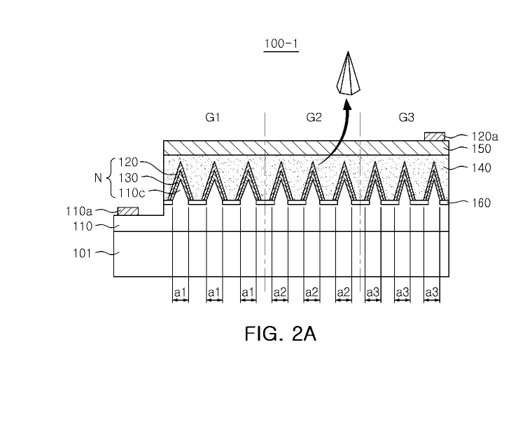

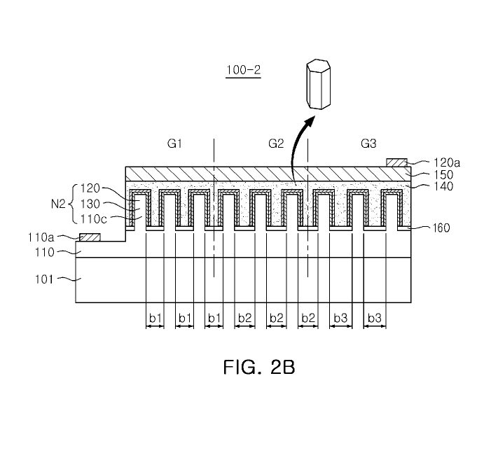

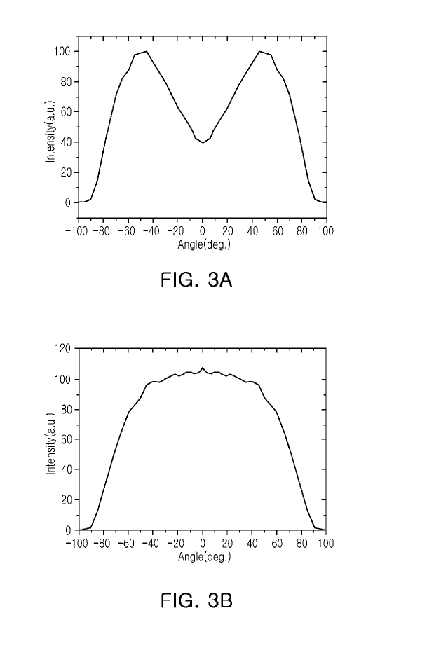

The light emitting device 100-2 may emit white light from a device unit without a wavelength converting caused by a separate wavelength converting material. In detail, a first group G1 of the light emitting device 100-2 may emit red light, a second group G2 of the light emitting device 100-2 may emit green light, and a third group G3 of the light emitting devices 100-2 may emit blue light, whereby white light can be emitted from the light emitting device 100-2 itself through color mixing therebetween. As the present inventive concept is not limited thereto, the light emitting device 100-2 may emit blue light, green light or red light. The detailed feature of the light emitting device 100-2 according to an embodiment of the present inventive concept will be explained hereinafter with reference to FIGS. 2 and 3.

FIGS. 2A and 2B are schematic cross-sectional views illustrating examples of a light emitting device which may be employed in a light emitting device package according to an exemplary embodiment of the present inventive concept.

With reference to FIG. 2A, the light emitting device 100-1 according to an embodiment of the present inventive concept may include a base layer 110 formed of a first conductivity-type semiconductor material, an insulating layer disposed on the base layer 110 and having a plurality of openings through which regions of the base layer 110 are exposed, and a plurality of light emitting nanostructures N.

The base layer 110 may be formed on substrate 101. The substrate 101 may be provided as a substrate for semiconductor growth, and may be formed of insulating, conductive, or semiconductor materials such as sapphire, SiC, MgAl₂O₄, MgO, LiAlO₂, LiGaO₂, GaN or the like. The sapphire has insulating properties and is a crystal having a Hexa-Rhombo R3c symmetry and having a lattice constant of 13.001 Å and a lattice constant of 4.758 Å, as well as a C(0001) plane, an A(11-20) plane, and an R (1-102) plane, and the like. In this case, the C plane may be mainly used as a substrate for nitride semiconductor growth because it facilitates growth of a nitride film and is stable at high temperatures.

In addition, for example, Si (silicon) may be used as a material for the substrate 101. The substrate formed of Si may facilitate mass production, since the substrate formed of Si is suitable for being manufactured at a relatively large diameter, and the production costs thereof are relatively low. When a Si substrate is used, a nucleation layer formed of a material such as AlₓGa₁₋ₓN is formed, and nitride semiconductor having the desired structure may be grown thereon.

The base layer 110 may be formed of a first conductivity-type semiconductor material and may be grown on the substrate 101 by using a semiconductor growth process such as Metal Organic Chemical Vapor Deposition (MOCVD), Hydride Vapor Phase Epitaxy (HVPE), Molecular Beam Epitaxy (MBE), or the like.

An insulating layer 160 may be disposed on the base layer 110. The insulating layer 160 may have a plurality of openings through which regions of the base layer 110 are exposed. The insulating layer 160 may be used as a mask for growing nanocores 110c. The insulating layer 160 may be an insulating material such as SiO₂ or SiNₓ which can be used in semiconductor processes.

In an embodiment of the present inventive concept, referring to FIG. 2A, the light emitting device 100-1 may include a plurality of light emitting nanostructures N. The plurality of light emitting nanostructures N may include a nanocore 110c disposed on each of the exposed regions of the base layer 110 and formed of a first conductivity-type semiconductor material, an active layer 130 surrounding the nanocore 110c, and a second conductivity-type semiconductor layer 120 surrounding the active layer 130. However, the present inventive concept is not limited thereto, and the first and second conductivity-type semiconductors may be n-type and p-type, respectively. The base layer 110, the nanocore 110c and the second conductivity-type semiconductor layer 102 may each include GaN, AlGaN, and InGaN materials having a compositional formula AlₓIn_{y}Ga_{1-y}N (where 0≦x≦1, 0≦y≦1, and 0≦x+y≦1).

In addition, the active layer 130 may emit light having a predetermined wavelength through the recombination of electrons and holes, and may have a multi-quantum well (MQW) structure, for example, an InGnN/GaN structure, in which quantum well and quantum barrier layers are alternately stacked.

In an embodiment of the present inventive concept, an filler 140 filling the space between the plurality of light emitting nanostructures N may be formed. A transparent electrode layer 150 may be disposed on the filler 140, and a second electrode 120a may be disposed on the transparent electrode layer 150 to be electrically connected to a second conductivity-type semiconductor layer 120. The filler 140 may be formed of a conductive material in order to electrically connect the second electrode 120a to the second conductivity-type semiconductor layer 120.

However, the present inventive concept is not limited thereto, and it is possible to form the filler 140 with an insulating material while forming the filler 140 to only partially cover an upper side of the light emitting nanostructures N, thereby forming a region in which the transparent electrode layer 150 and second conductivity-type semiconductor layer 120 can be directly connected. A first electrode 110a for applying an electrical signal to the base layer 110 may be disposed in a region of the base layer 110 in which the light emitting nanostructures N are not disposed.

Meanwhile, as explained above, the light emitting device 100-1 may emit white light from a device unit. For example, the plurality of the light emitting nanostructures N may be divided into first to third groups G1 to G3, and densities of indium included in the first to third groups G1 to G3 of the active layer 130 may be different from one another. As illustrated in FIG. 2A, the difference can be achieved by setting the diameter of nanocores 110C to be different. That is, the light emitting nanostructures N belonging to the first group G1 may have the greatest diameter a1 among diameters a1-a3, and the wavelength emitted from the light emitting nanostructures N belonging to the first group G1 may be red light having the longest wavelength. Similarly, the light emitting nanostructures N belonging to the second group G2 may have a diameter a2, smaller than the diameter a1 of the light emitting nanostructures N belonging to the first group G1 and greater than a diameter a3 of the light emitting nanostructures N belonging to the third group G3, and the wavelength emitted from the light emitting nanostructures N belonging to the second group G2 may be, for example, green light. The light emitting nanostructures N belonging to the third group G3 may have the smallest diameter among the diameters a1-a3, and the wavelength emitted from the light emitting nanostructures N belonging to the third group G3 may be blue light having the shortest wavelength. As explained above, the diameters a1, a2 and a3 of the nanocores 110c of the first to third groups G1 to G3 may be controlled by changing the size of the openings of the insulating layer 160 formed on the base layer 110.

The density of indium of the active layer 130 included in the first to third groups G1 to G3 may be implemented by differently setting distances b1, b2 and b3 between the nanocores 110c as illustrated in FIG. 2B. For example, the distance b1 between the light emitting nanostructures N2 belonging to the first group G1 may be the smallest among the distances b1-b3, the distance b2 between the light emitting nanostructures N2 belonging to the second group G2 may be greater than the distance b1 between the light emitting nanostructures N2 belonging to the first group G1 and smaller than the distance b3 between the light emitting nanostructures N2 belonging to the third group G3, and the distance b3 between the light emitting nanostructures N2 belonging to the third group G3 may be the greatest among the distances b1-b3. The distances b1, b2, and b3 between the light emitting nanostructures N2 belonging to the first to third groups G1, G2, and G3 may be controlled by changing the distance between openings of an insulating layer 160 formed on the base layer 110.

The wavelengths of light emitted from the light emitting nanostructures N and N2 belonging to the first to third groups G1, G2 and G3 may differ from one another, depending on the density of indium of the active layer 130 included in the light emitting nanostructures N (see FIG. 2A) and N2 (see FIG. 2B) belonging to the first to third groups G1, G2 and G3. That is, the first group G1 may emit red light, the second group G2 may emit green light, and the third group G3 may emit blue light, whereby white light may be emitted from the light emitting devices 100-1 and 100-2 through color mixing therebetween.

When such a light emitting device 100-1 and 100-2 is used, the light emitting package 10-1 may not be required to be equipped with separate wavelength conversion materials. In further detail, the resin portion 11 may not be equipped with wavelength conversion materials, for example, a phosphor or quantum dot.

Meanwhile, when the resin portion 11 is equipped with wavelength conversion materials, the wavelength conversion materials may perform the role of scattering light emitted from light emitting devices 100-1 and 100-2. However, in the light emitting device package 10-1 according to an embodiment of the present inventive concept, since the resin portion does not include the wavelength conversion materials, a light scattering effect may be decreased, whereby a decrease in light extraction efficiency may occur.

In addition, even though white light is not directly emitted from the light emitting devices 100-1 and 100-2 due to the structure of the active layer 130, the light emitting devices 100-1 and 100-2 may have a maximum luminescence intensity in a direction parallel with the plane on which the light emitting devices 100-1 and 100-2 are mounted, or at a predetermined angle of at least θₐ (see FIG. 1) with respect to a direction perpendicular with respect to the plane on which the light emitting devices 100-1 and 100-2 are mounted, rather than in the direction perpendicular with respect to the plane on which the light emitting devices 100-1 and 100-2 are mounted.

It will be understood that the above explained feature is due to the protruding structure of the active layer 130 of the light emitting devices 100-1 and 100-2. In further detail, the light emitting nanostructures N and N2 may be formed to have a pyramidal shape as illustrated in FIGS. 2A and 2B, or may be formed to have a polygonal pillar shape, for example, a hexagonal pillar shape. In other words, since the active layers 130 of the light emitting devices 100-1 and 100-2 may be formed to have a protruding shape, light emitted from the light emitting devices 100-1 and 100-2 may have higher light extraction efficiency in a lateral direction than in a vertical direction. More specifically, as illustrated in FIG. 3A, the light emitting devices 100-1 and 100-2, according to an embodiment of the present inventive concept, have maximum luminescence intensity at an angle of at least 40° with respect to a direction perpendicular with respect to the light emitting device 100-1. The embodiment of FIG. 3A may have a disadvantage over the conventional light emitting device (as illustrated in FIG. 3B) in which most of light from the light emitting devices 100-1 and 100-2 is emitted within the angle ranging from a vertical direction to 40° with respect to the direction perpendicular with respect to the light emitting devices 100-1 and 100-2.

With reference to FIG. 1, when light from the light emitting device 100-2 is emitted externally, light incident in a direction outside of a critical angle θ_{c} of total internal reflection may be entirely reflected internally without being externally extracted due to the difference between a refractive index of the resin portion 11 and a refractive index of an external medium (for example, air). When the refractive index of the resin portion n_{A} is about 1.5 and the refractive index of air n_{B} is 1, the critical angle of total internal reflection is arcsin(n_{B}/n_{A}), which is about 41.8°, a numeric value similar to that of the angle at which the luminescence intensity of the light emitting device 100-2 according to an embodiment of the present inventive concept reaches on a maximum value. Therefore, when a light emitting device 100-2 according to the embodiment of FIG. 2B is mounted in a package, light extraction efficiency may deteriorate.

According to an embodiment of the present inventive concept, the light emitting device package 10-1 may further include a light scattering agent 12 dispersed in the resin portion and formed of a material having a refractive index higher than that of a material forming the resin portion.

The light scattering agent 12 may be a material selected from Al₂O₃, TiO₂, or combinations thereof, whose refractive indices thereof are 1.78 and 2.8, respectively. Based on the refractive index difference of an embodiment of the present inventive concept, light emitted by light emitting device 100-2 may be scattered by the light scattering agent 12 within the resin portion, thereby enhancing the light extraction efficiency of the light emitting device package 10-1.

In an embodiment of the present inventive concept, referring to FIG. 1, the size (radius: d₁/2) of the light scattering agent 12 may be determined within the range of from 1 μm to 10 μm, and the light extraction efficiency may be changed according to the size (radius: d₁/2) and density of the light scattering agent 12. The present inventive concept is not limited thereto, and it may be designed that as the size (radius: d₁/2) of the light scattering agent 12 increases, the density of the light scattering agent 12 also increases.

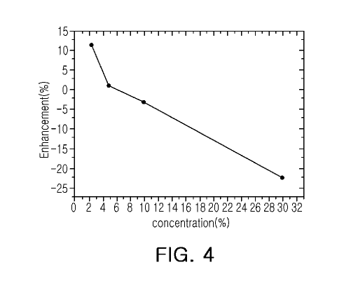

FIG. 4 is a graph of experimental results illustrating a relationship between a density of light scattering agent and light extraction efficiency.

In an experiment with an embodiment of the present inventive concept, the light scattering agent 12 was formed of Al₂O₃, the size (radius: d₁/2) of which was 1.5 μm. Luminescence intensity of the light emitting device package 10-1 was measured by changing a weight ratio of the light scattering agent 12 with respect to the resin portion 11. In the experiment with the embodiment, the luminescence intensity was set based on a case in which the light scattering agent 12 is not included (0%) in the resin portion 11.

The experimental results, together with an experimental graph illustrated in FIG. 4, confirm that when a weight ratio of the light scattering agent 12 is in the range of 1% to 5% with respect to the weight of the resin portion 11, the light emitting device package 10-1 may have relatively excellent luminescence intensity as compared to that of a light emitting device package 10-1 not having the light scattering agent 12. In detail, it can be appreciated that when 2.5% of the light scattering agent 12 with respect to the weight of the resin portion 11 was included in the resin portion, luminescence intensity of the light emitting device package 10-1 was increased by around 11.5% as compared to the case in which the light scattering agent 12 was not included therein. As described above, since a weight ratio of the light scattering agent may be changed depending on the size (radius: d₁/2) of light scattering agents particle, the present inventive concept is not limited to that described above. For example, a weight ratio of the light scattering agent may be determined to be within a range of 1% to 50% of the resin portion with respect to the weight of the resin portion.

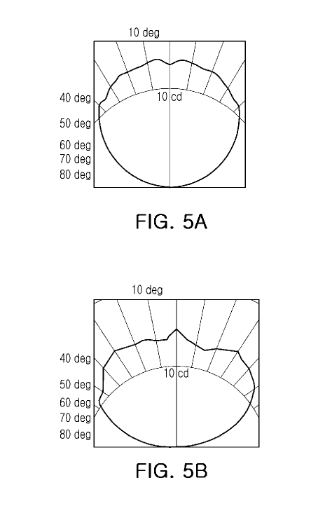

FIGS. 5A and 5B are graphs comparing orientation angle properties of a light emitting device package according to an exemplary embodiment of the present inventive concept and a light emitting device package in which a light scattering agent is not included.

With reference to FIG. 5A and 5B, it can be appreciated that in the case of the light emitting device package 10-1 (see FIG. 1) according to an embodiment of the present inventive concept, an angle of beam spread of light emitted by the light emitting device package 10-1 was reduced to 120° from 134° (see FIG. 5A), as compared to the case in which the light scattering agent 12 was not included therein (see FIG. 5B). Here, light emitted by the light emitting device 100-2 (see also FIG. 2B) was scattered by the light scattering agent 12, such that a ratio at which the light was incident onto an interface between the resin part 11 and an external material (air) at an angle smaller than a critical angle of total internal reflection of light was relatively increased.

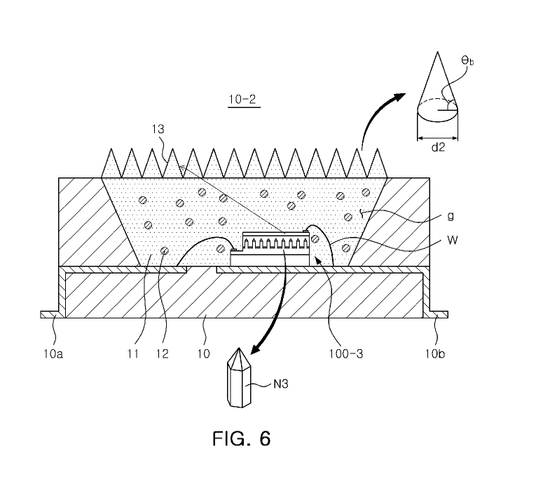

FIG. 6 is a schematic cross-sectional view illustrating a light emitting device package according to another exemplary embodiment of the present inventive concept.

Referring to FIG. 6, the light emitting device package 10-2 according to an embodiment of the present inventive concept may include a package substrate 10, light emitting device 100-3 mounted on the package substrate 10, and a resin portion 11 formed on the package substrate 10 and sealing the light emitting device 100-3. In the following description, only changed constitutions will be explained, and thus, descriptions that are the same as those of previous embodiments as shown in FIG. 1 will be omitted.

In an embodiment of the present inventive concept, referring to FIG. 6, the light emitting device package 10-2 may include a plurality of protruding portions 13 disposed on an upper surface of the resin portion 11. The protruding portions 13 may be formed to have a cone shape. In this case, since light emitted by light emitting device 100-3 may be incident onto the interface between the resin portion 11 and external material at various angles, light extraction may be facilitated.

Even though the present inventive concept is not limited thereto, the diameter of a base plane d₂ of the plurality of protruding portions having a cone shape may range from 10 μm to 20 μm. A range of an acute angle θ_{b} (see FIG. 6) between a base plane and a side plane of the cone shape is from (90°−θ_{c})−20° to (90°−θ_{c})+20°, where θc (see FIG. 1) is a critical angle at which light emitted by the light emitting device passes through the resin portions and is entirely reflected internally without being emitted externally. For example, when the refractive index of the resin portion 11 is 1.5, and the refractive index of an external material, air, is 1, the critical angel is 41.8°, and in this case, a range of the acute angle θ_{b} between a base plane and a side plane of the cone shape may be determined to be in the range from 28.2° to 68.2°.

In an embodiment of the present inventive concept, the light emitting device 100-3 may include a plurality of light emitting nanostructures N3, and it is depicted that the plurality of light emitting nanostructures N3 may be formed to have a polygonal pillar and pyramidal shape, unlike the embodiment shown in FIGS. 2A and 2B. However, as the present inventive concept is not limited thereto, the light emitting package 10-2 according to an embodiment of the present inventive concept may include a shape of light emitting device 100-1 and 100-2 depicted in FIGS. 2A and 2B.

According to an embodiment of the present inventive concept, by forming a plurality of protruding portions on an upper surface of the resin portion 11, the plurality of the protruding portions corresponding to a plurality of light emitting nanostructures N3, the active layer 130 may have a protruding shape, whereby the light extraction efficiency of the light emitting package 10-2 may be increased.

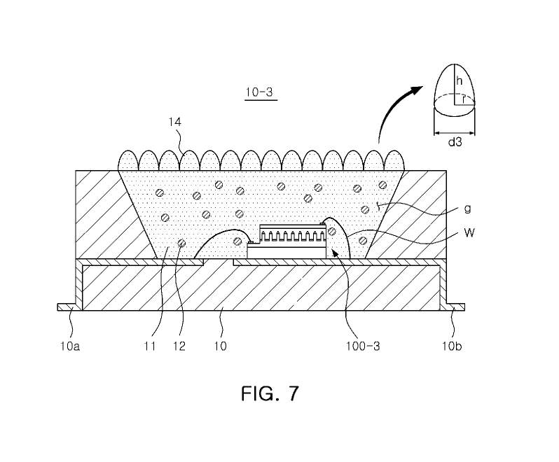

Meanwhile, the shape of the plurality of protruding portions according to the present inventive concept is not limited to a cone shape. In particular, the plurality of protruding portions 14 may include a dome shape as illustrated in a light emitting package 10-3 of FIG. 7.

Here, the dome shape refers to a protruding portion, cross-sectional view thereof, which appears in the following aspherical surface equation where a conic efficient k is −1, having a parabolic shape. (Z is a distance in coaxial directions from a peak of a dome shape, R is a radius of curvature, H is a reference height of optical axis, k is a conic coefficient, a₁, a₂ and a₃ are aspherical coefficients.)

$$Z ( H ) = \frac{{H}^{2}}{R ( 1 + \sqrt{1 - ( 1 + k ) \frac{{H}^{2}}{{R}^{2}}} )} + {a}_{1} {H}^{2} + {a}_{2} {H}^{4} + {a}_{3} {H}^{6} + …$$

In the embodiment of FIG. 7, the aspect ratio (h/r) of the dome shape may be greater than 0.5. For example, the aspect ratio (h/r) of the dome shape may be 1. In addition, the diameter d₃ of bottom plane of dome-shaped protruding portions 14 may be from 10 μm to 20 μm. The plurality of protruding portions of FIGS. 6 and 7 are formed by using a stamp imprinting. In addition, the shapes of the plurality of protruding portions are not limited to a cone or a dome. Accordingly, the plurality of protruding portions may be formed to have a circular shape, including a convex shape.

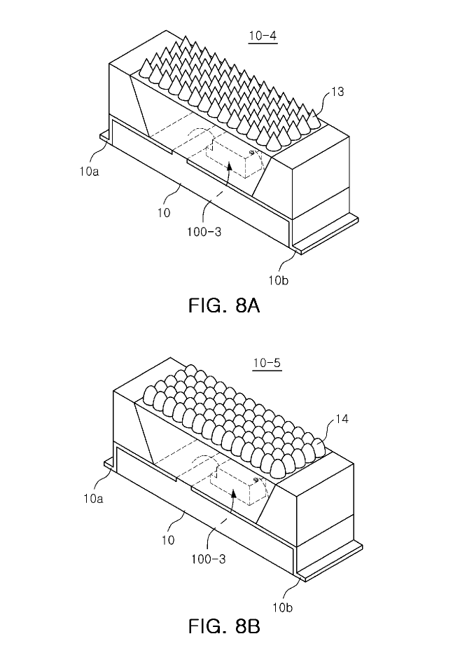

FIGS. 8A and 8B are perspective views schematically illustrating light emitting device packages according to another exemplary embodiment of the present inventive concept.

The embodiments of FIGS. 8A and 8B, which show light emitting device packages 10-4 and 10-5, respectively, are same as those of FIGS. 6 and 7, except that the resin portion does not include a light scattering portion. That is, in an embodiment of the present inventive concept, the plurality of protruding portions may not be necessarily formed on an upper surface of resin portions in which a light scattering agent is dispersed, and may be formed on an upper surface of resin portions in which a light scattering agent is not dispersed.

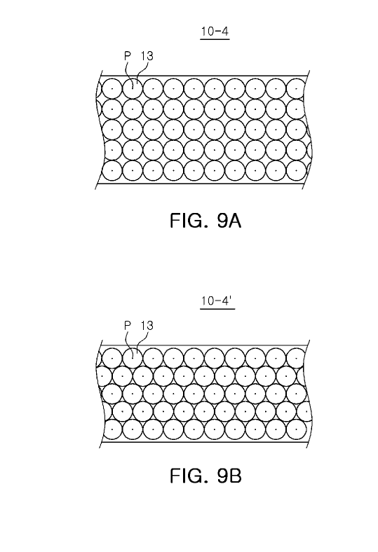

FIGS. 9A and 9B are schematic plan views 10-4 and 10-4′, viewed from the top of the light emitting device packages 10-4 and 10-5 according to an exemplary embodiment of FIGS. 8A and 8B, respectively. In detail, when an apex of a cone shape protruding portion is P, the plurality of protruding portions 13 may be arranged to form a matrix as shown in FIG. 9A. On the other hand, as shown in FIG. 9B, the plurality of protruding portions 13 may also be arranged to form a zigzag shape.

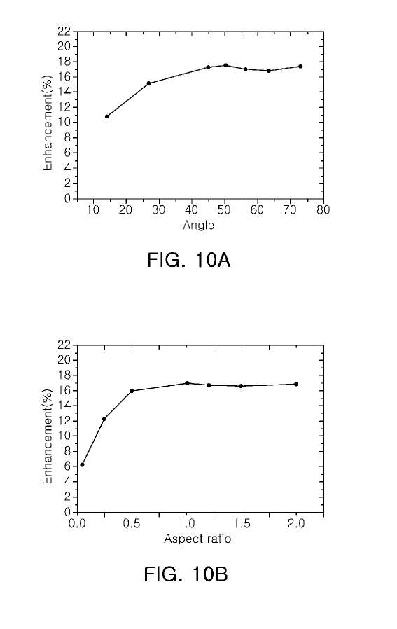

FIG. 10A is a graph illustrating a relationship between light extraction efficiencies according to a change in an angle of protruding portions of light emitting device packages according to the exemplary embodiment of FIG. 8A.

In detail, a diameter d₂ (see FIG. 6) of a button plane of the cone shape is set to be 20 μm, and a relationship between light extraction efficiencies is measured by changing a range of an acute angle θ_{b} (see FIG. 6) between a base plane and a side plane of the cone shape.

With reference to the result of FIG. 10A, when an acute angle θ_{b} between a base plane and a side plane of the cone shape is 50°, it was confirmed that luminescence intensity of the light emitting device package of the embodiment of FIG. 8A was increased by around 17.6% as compared to a light emitting device package in which a plurality of protruding portions 13 were not formed.

FIG. 10B is a graph illustrating a relationship between light extraction efficiencies according to a change in aspect ratios (h/r) of protruding portions of light emitting device package 10-5 according to the exemplary embodiment of FIG. 8B.

In detail, a diameter d₃ (see FIG. 7) of a button plane of the cone shape may be set to be 20 μm, and a relationship between light extraction efficiencies may be measured by changing an aspect ratio of dome shape protruding portions of light emitting device package.

With reference to the result of FIG. 10B, when an aspect ratio of dome shape is 1.0, it was confirmed that luminescence intensity of the light emitting device package of the embodiment of FIG. 8B was increased by around 17.1% as compared to a light emitting device package in which a plurality of protruding portions 14 were not formed.

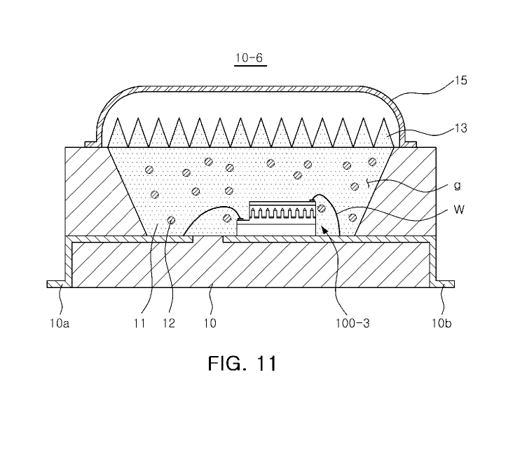

FIG. 11 is a schematic cross-sectional view illustrating a light emitting device package according to another exemplary embodiment of the present inventive concept.

It will be understood that the embodiment of FIG. 11 is identical to the embodiment of FIG. 6, except that it further includes a cover part 15 covering an upper surface of resin portion 11.

In some cases, during the usage of a light emitting device package 10-6 in which a plurality of protruding portions are formed, foreign objects such as dust or the like may accumulate between the plurality of protruding portions, which may result in a problem of a reduction of luminescence intensity of the light emitting device package. However, according to the embodiment of FIG. 11, the problem in which dust accumulates between the plurality of protruding portions may be prevented by the cover part 15 covering the plurality of protruding portions. In this case, the cover part 15 may be formed of a transparent material and be formed to be positioned separately from the plurality of protruding portions 13 by a predetermined distance.

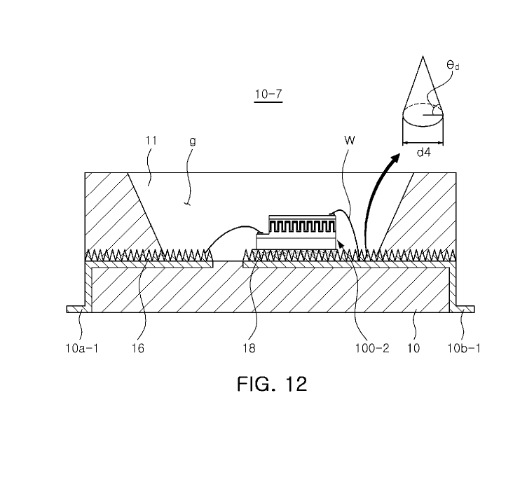

FIG. 12 is a schematic cross-sectional view illustrating a light emitting device package 10-7 according to another exemplary embodiment of the present inventive concept.

Referring to FIG. 12, a light emitting device package according to an embodiment of the present inventive concept may include a package substrate 10, a light emitting device 100-2 mounted on the package substrate 10 including a plurality of light emitting nanostructures, and a resin portion 11 formed on the package substrate 10 and sealing the light emitting device 100-2. Hereinafter, changed constitutions excluding matters similarly applied to the embodiment as shown in FIG. 1 will be explained.

In the embodiment of FIG. 12, the package substrate 10 may include a first and a second lead frame 10a-1 and 10b-1. The present inventive concept is not limited thereto, and the light emitting device 100-2 may be mounted on an upper side of one of the first and second lead frames 10a-1 and 10b-1. FIG. 12 illustrates that the light emitting device 100-2 is mounted on an upper surface of the second lead frame 10b-1. In this case, an adhesive part 18 for fixing the light emitting device 100-2 may be formed between the light emitting device 100-2 and the lead frame (the second lead frame 10b-1) on which the light emitting device 100-2 is mounted. The adhesive part 18 may be formed of a material suitable for fixing the light emitting device 100-2 on a mounted position during the manufacturing process of the light emitting device package and during the time in which the light emitting device package is in use. For example, the adhesive part 18 may be formed of a conductive and/or insulating material, and may also be formed of an optical reflective material and/or a transparent material.

In an embodiment of the present inventive concept, one or more of the first and second lead frames 10a-1, 10b-2 may include a plurality of protruding portions disposed on an upper surface thereof. Accordingly, light emitted by a light emitting device 100-2 may be scattered by a plurality of protruding portions 16, thereby diversifying the optical path and enhancing light extraction efficiency of the light emitting package 10-7. For an improved effect, the first and second lead frames 10a-1 and 10b-2 may be formed of metallic materials having high degrees of conductivity and high optical reflectivity. Moreover, according to an embodiment of the present inventive concept, adhesive strength between the lead frames 10a-1 and 10b-1 and the resin portion 11 may be enhanced by the protruding portions 16 formed on the lead frames 10a-1 and 10b-1, thereby effectively preventing the phenomenon in which the resin portions 11 are delaminated.

In an embodiment of the present inventive concept, the plurality of protruding portions 16 may be formed to have a cone shape (see FIG. 12).

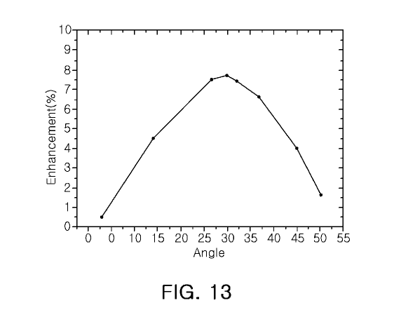

FIG. 13 is a graph illustrating a relationship between light extraction efficiencies according to a change in a shape of protruding portions of light emitting device packages 10-7 according to an exemplary embodiment of FIG. 12.

In detail, in the embodiment of FIG. 13, a diameter of a base plane d₄ of the cone shape is set to be 20 μm, and relationships between light extraction efficiencies are measured by changing a range of an acute angle θ_{d} (see FIG. 12) between a base plane and a side plane of the cone shape.

With reference to the result of FIG. 13, when an acute angle θ_{d} between a base plane and a side plane of the cone shape is smaller than 50°, it is confirmed that luminescence intensity of the light emitting device package of the embodiment of FIG. 13 was increased as compared to a light emitting device package in which a plurality of protruding portions 13 were not formed. In particular, when the acute angle θ_{d} ranges from 20° to 40°, luminescence intensity of the light emitting device may be increased by around 6% or more, and when the acute angle is 30°, luminescence intensity of the light emitting device may be increased by around 7.7% or less.

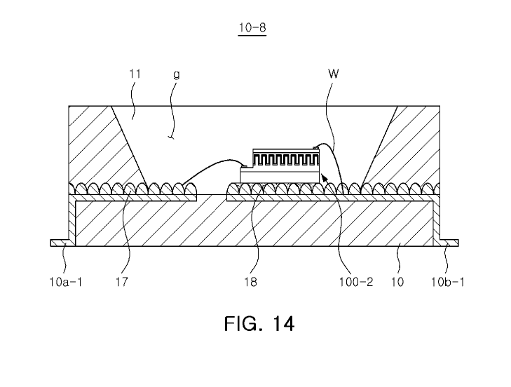

FIG. 14 is a schematic cross-sectional view illustrating a light emitting device package modified from a light emitting device package according to a modified exemplary embodiment of FIG. 12.

The plurality of protruding portions 17 formed on a first lead frame 10a-1 and a second lead frame 10b-1, according to the embodiment of FIG. 14, may be formed to have a dome shape, as illustrated in FIG. 14. Here, the dome shape refers to a protruding portion, and a cross-sectional view thereof, which appears in the aspherical surface equation when a conic efficient k is −1, has a parabolic shape. (Z is a distance in coaxial directions from a peak of a dome shape, R is a radius of curvature, H is a reference height of optical axis, k is a conic coefficient, and a₁, a₂ and a₃ are aspherical coefficients.)

$$Z ( H ) = \frac{{H}^{2}}{R ( 1 + \sqrt{1 - ( 1 + k ) \frac{{H}^{2}}{{R}^{2}}} )} + {a}_{1} {H}^{2} + {a}_{2} {H}^{4} + {a}_{3} {H}^{6} + …$$

According to the embodiment of FIG. 14, when light emitted by the light emitting device 100-2 is reflected from the lead frames 10a-1 and 10b-1, as optical paths become diversified due to scattering of the plurality of protruding portions 17, light extraction efficiency of the light emitting device package 10-8 may be enhanced.

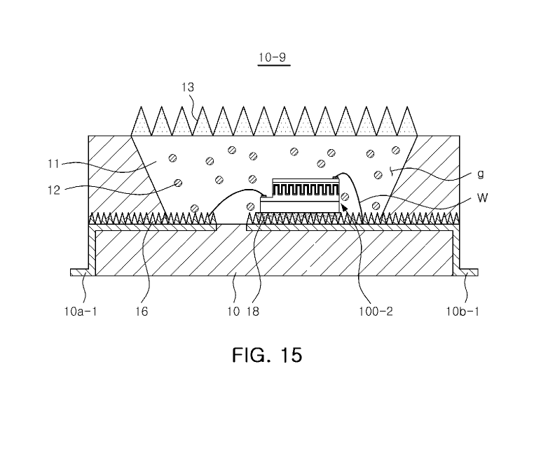

FIG. 15 is a schematic cross-sectional view illustrating a light emitting device package according to another exemplary embodiment of the present inventive concept. In the embodiment of FIG. 15, the light emitting device package 10-9 may include a package substrate 10 including first and second lead frames 10a-1 and 10b-1, a light emitting device 100-2 mounted on the package substrate 10 and including a plurality of light emitting nanostructures, and a resin portion 11 formed on the package substrate 10 and sealing the light emitting device 100-2.

In the embodiment of FIG. 15, the light emitting device package 10-9 may include a light scattering agent 12 dispersed in the resin portion 11 and formed of a material having a refractive index higher than that of a material forming the resin portion 11. In addition, the plurality of protruding portions 13 may be formed to have at least a cone shape or a dome shape, and one or more of the first and second lead frames 10a-1 and 10b-1 may include a plurality of protruding portions 16 disposed on an upper surface thereof.

Meanwhile, in the embodiment of FIG. 15, a light scattering agent 12, a plurality of protruding portions 13 and 14 formed on an upper surface of a resin portion 11, and a plurality of protruding portions 16 and 17 disposed on an upper surface of lead frames 10a-1 and 10b-1, which are structural elements of a light emitting device package, do not have to be exclusively applied. In other word, a light emitting device package including all of the elements is an exemplary embodiment of the present inventive concept.

According to the embodiment of FIG. 15, in a light emitting device package employing a light emitting device having light emitting nanostructures, light extraction efficiency may be effectively enhanced.

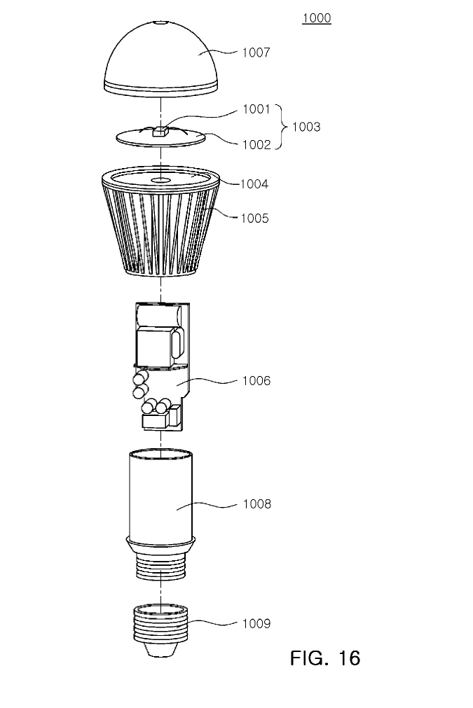

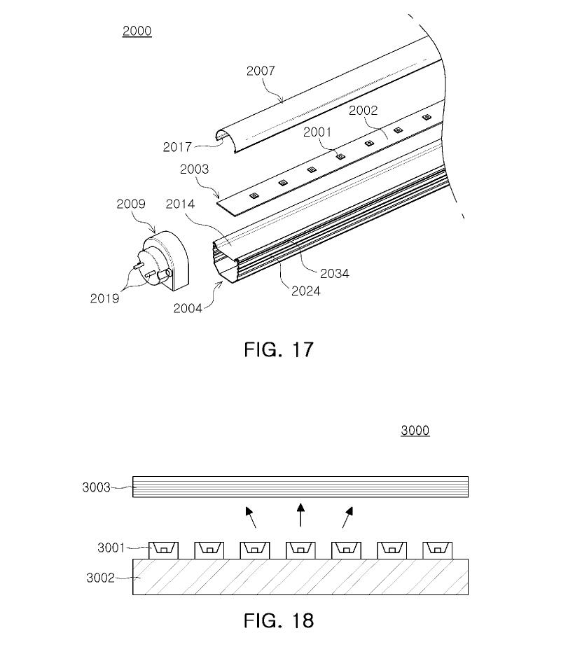

FIGS. 16 and 17 are exploded perspective views illustrating an example of a lighting device 1000 and 2000 to which a light emitting device package 10-1 to 10-9 according to an embodiment of the present inventive concept is applied.

The lighting device 1000 may be a bulb-type lamp as illustrated in FIG. 16 and may have a shape similar to an incandescent lamp to be substituted with the incandescent lamp according to the related art, but is not limited thereto. The lighting device 1000 may emit light having light properties (color and color temperature) similar to those of incandescent lamps.

Referring to the exploded perspective view of FIG. 16, the lighting device 1000 may include a light emitting module 1003, a driving unit 1006, and an external connector unit 1009. In addition, exterior structures such as an external housing 1005, an internal housing 1008, and a cover unit 1007 may be additionally included. The light emitting module 1003 may include a light source 1001 and a circuit board 1002 having the light source 1001 mounted thereon. The embodiment of FIG. 16 illustrates a case in which a single light source 1001 is mounted on the circuit board 1002. However, if necessary, a plurality of light sources may be mounted thereon. Here, the light source 1001 may be the light emitting device package 10-1 to 10-9 described in the foregoing embodiments.

In the lighting device 1000, the light emitting module 1003 may include the external housing 1005 serving as a heat radiating part, and the external housing 1005 may include a heat sink plate 1004 being in direct contact with the light emitting module 1003 to improve heat dissipation. The cover unit 1007 may be disposed above the light emitting module 1003 and have a convex lens shape. The driving unit 1006 may be disposed inside the internal housing 1008 and receive power from the external connector unit 1009, which is similar to a socket structure. In addition, the driving unit 1006 may convert the received power into a current source appropriate for driving the light source 1001 of the light emitting module 1003 and supply the converted current source thereto. For example, the driving unit 1006 may include a rectifying part and a DC/DC converter.

The lighting device 2000 may be a bar-type lamp as illustrated in FIG. 17 and have a shape similar to a fluorescent lamp so as to be substituted with the fluorescent lamp according to the related art, but is not limited thereto. The lighting device 2000 may emit light having light properties similar to those of the fluorescent lamp.

Referring to the exploded perspective view of FIG. 17, the lighting device 2000 according to an exemplary embodiment of the present inventive concept may include a light source module 2003, a body part 2004, and a terminal part 2009 and may further include a cover part 2007 covering the light source module 2003.

The light source module 2003 may include a substrate 2002 and a plurality of light sources 2001 mounted on the substrate 2002. The light source 2001 may be the semiconductor light emitting device package 10-1 to 10-9 described in the foregoing embodiments.

The body part 2004 may have the light source module 2003 mounted on one surface thereof to be fixed thereto. The body part 2004 may be a sort of support structure and include a heat sink. The body part 2004 may be formed of a material having high thermal conductivity so as to externally emit heat generated from the light source module 2003. For example, the body part 2004 may be formed of a metal material, but is not limited thereto.

The body part 2004 may have an elongated bar shape corresponding to a shape of the substrate 2002 of the light source module 2003. The body part 2004 may have a recess 2014 formed in a surface thereof on which the light source module 2003 is mounted, the recess 2014 being capable of receiving the light source module 2003 therein.

A plurality of heat radiating fins 2024 for the radiation of heat may be formed on both outer side surfaces of the body part 2004 so as to protrude therefrom. In addition, catching grooves 2034 may be formed at both distal ends of the outer side surfaces disposed above the recess 2014, the catching grooves 2034 extending in a length direction of the body part 2004. The cover part 2007, to be described later, may be coupled to the catching grooves 2034.

Both ends of the body part 2004 in the length direction may be opened, and thus, the body part 2004 may have a pipe shape having both ends open. The embodiment of FIG. 17 illustrates a structure of the body part 2004 in which both ends thereof are open, but is not limited thereto. For example, either of both ends of the body part 2004 may be open.

The terminal part 2009 may be provided in one or more open ends of both ends of the body part 2004 in the length direction and supply power to the light source module 2003. The embodiment illustrates that both ends of the body part 2004 are opened and have respective terminal parts 2009 provided therein. However, the present inventive concept of FIG. 17 is not limited thereto and, for example, the terminal part 2009 may be provided in one open end of both ends of the body part 2004.

The terminal parts 2009 may be respectively coupled to and cover both open ends of the body part 2004. Each of the terminal parts 2009 may include electrode pins 2019 protruded outwardly.

The cover part 2007 may be coupled to the body part 2004 and cover the light source module 2003. The cover part 2007 may be formed of a light transmissive material.

The cover part 2007 may have a curved semicircular surface to enable light to be generally emitted externally in a uniform manner. In addition, a base plane of the cover part 2007 coupled to the body part 2004 may be provided with protrusions 2017 formed in the length direction of the cover part 2007 and engaged with the catching grooves 2034 of the body part 2004.

The embodiment of FIG. 17 illustrates that the cover part 2007 has a semicircular shape, but the cover part 2007 is not limited thereto. For example, the cover part 2007 may have a flat quadrangular shape and may also have other polygonal shapes. Such a shape of the cover part 2007 may be variously changed depending on the design of a lighting device from which light is emitted.

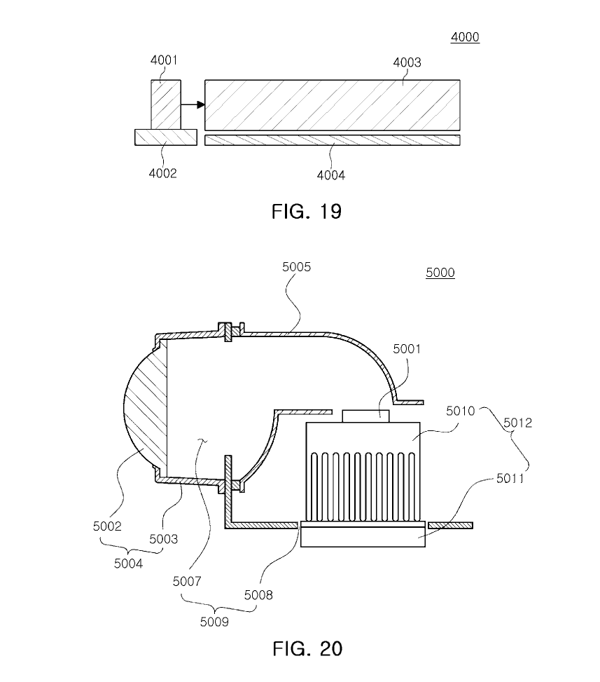

FIGS. 18 and 19 illustrate examples of a backlight unit to which a light emitting device package 10-1 to 10-9 according to an embodiment of the present inventive concept is applied.

Referring to FIG. 18, a backlight unit 3000 may include a light source 3001 mounted on a substrate 3002 and one or more optical sheet 3003 disposed thereabove. The light source 3001 may be the light emitting device package 10-1 to 10-9 having the above described structure or a structure similar thereto.

The light source 3001 in the backlight unit 3000 of FIG. 18 may emit light toward a liquid crystal display (LCD) device disposed thereabove. On the other hand, referring to FIG. 19, a light source 4001 mounted on a substrate 4002 in a backlight unit 4000 according to another embodiment illustrated in FIG. 19 may emit light laterally and the emitted light may be incident to a light guide plate 4003 such that the backlight unit 4000 may serve as a surface light source. The light that has passed through the light guide plate 4003 may be emitted upwardly and a reflective layer 4004 may be formed under a base plane of the light guide plate 4003 in order to improve light extraction efficiency. The light source 3001 may be the light emitting device package 10-1 to 10-9 having the above described structure or a structure similar thereto.

FIG. 20 illustrates an example of a headlamp to which a light emitting device package 10-1 to 10-9 according to an embodiment of the present inventive concept is applied. Referring to FIG. 20, a headlamp 5000 used as a vehicle lighting element, or the like, may include a light source 5001, a reflective unit 5005 and a lens cover unit 5004, the lens cover unit 5004 including a hollow guide part 5003 and a lens 5002. The headlamp 5000 may further include a heat radiating unit 5012 externally dissipating heat generated by the light source 5001. The heat radiating unit 5012 may include a heat sink 5010 and a cooling fan 5011 in order to effectively dissipate heat. In addition, the headlamp 5000 may further include a housing 5009 allowing the heat radiating unit 5012 and the reflective unit 5005 to be fixed thereto and supported thereby. One surface of the housing 5009 may be provided with a central hole 5008 into which the heat radiating unit 5012 is inserted to be coupled thereto. The other surface of the housing 5009 integrally connected to and bent in a direction perpendicular to the one surface of the housing 5009 may be provided with a forward hole 5007 such that the reflective unit 5005 may be disposed above the light source 5001. Accordingly, a forward side may be opened by the reflective unit 5005 and the reflective unit 5005 may be fixed to the housing 5009 such that the opened forward side corresponds to the forward hole 5007, whereby light reflected by the reflective unit 5005 disposed above the light source 5001 may pass through the forward hole 5007 and thereby be emitted outwardly. In the exemplary embodiment, the light source 5001 may include the semiconductor light emitting device package 10-1 to 10-9 described in the foregoing embodiments.

As set forth above, according to exemplary embodiments of the present inventive concept, a light emitting device package employing a light emitting device having light emitting nanostructures with effectively enhanced light extraction efficiency may be obtained.

While exemplary embodiments have been shown and described above, it will be apparent to those skilled in the art that modifications and variations could be made without departing from the spirit and scope of the present disclosure as defined by the appended claims.

1. A light emitting device package, comprising:
a package substrate;
a light emitting device disposed on the package substrate and including a plurality of light emitting nanostructures;
a resin portion disposed on the package substrate and sealing the light emitting device; and
a light scattering agent dispersed in the resin portion and including a material having a refractive index greater than a refractive index of a material forming the resin portion.

2. The light emitting device package of claim 1, wherein the light scattering agent is a material selected from the group consisting of Al₂O₃, TiO₂, and combinations thereof.

3. The light emitting device package of claim 1, wherein a weight ratio of the light scattering agent to the resin portion is in the range of 1% to 50%.

4. The light emitting device package of claim 1, wherein blue light, red light, green light, or white light is emitted by the light emitting device and the resin portion is free of light wavelength converting materials.

5. The light emitting device package of claim 1, wherein light emitted by the light emitting device has a maximum luminescence intensity at an angle of at least 40° with respect to a direction perpendicular with a surface on which the light emitting device is disposed.

6. The light emitting device package of claim 1, wherein the light emitting device comprises:
a base layer including a first conductivity-type semiconductor material;
an insulating layer disposed on the base layer and having a plurality of openings through which regions of the base layer are exposed; and
a plurality of light emitting nanostructures disposed on each of the exposed regions of the base layer and including a nanocore including a first conductivity-type semiconductor material, an active layer, and a second conductivity-type semiconductor layer, sequentially disposed on side planes of the nanocore.

7. The light emitting device package of claim 1, wherein the light emitting nanostructures have at least one of a polygonal pillar shape and a pyramidal shape.

8. The light emitting device package of claim 1, further comprising a plurality of protruding portions having at least one of a cone shape and a dome shape, disposed on an upper surface of the resin portion.

9. The light emitting device package of claim 8, wherein the plurality of protruding portions have cone shapes, and a range of an acute angle between a base plane and a side plane of the cone shape is from (90°−θ_{c})−20° to (90°−θ_{c})+20°, where θ_{c} is a critical angle in which light emitted by the light emitting device passes through the resin portions and is entirely reflected internally without being emitted externally.

10. The light emitting device package of claim 9, wherein a range of the acute angle between the base plane and the side plane of the cone shape is from 28.2° to 68.2°.

11. The light emitting device package of claim 8, wherein the plurality of protruding portions have dome shapes and an aspect ratio of the dome shape is greater than 0.5.

12. The light emitting device package of claim 1, wherein the package substrate includes first and second lead frames, and at least one of the first and second lead frames include a plurality of protruding portions disposed on an upper surface thereof.

13. The light emitting device package of claim 12, wherein the plurality of protruding portions have at least one of a cone shape and a dome shape.

14. The light emitting device package of claim 13, wherein the plurality of protruding portions have cone shapes, and a range of an acute angle between a base plane and a side plane of the cone shape is 50° or less.

15. The light emitting device package of claim 14, wherein the range of acute angle between the base plane and the side plane of the cone shape is from 20° to 40°.

16. A light emitting device package, comprising:
a package substrate;
a light emitting device disposed on the package substrate and including a plurality of light emitting nanostructures;
a resin portion disposed on the package substrate and sealing the light emitting device; and
a plurality of protruding portions having at least one of a cone shape and a dome shape and disposed on an upper surface of the resin portion.

17. (canceled)

18. (canceled)

19. (canceled)

20. The light emitting device package of claim 16, wherein the package substrate includes first and second lead frames, and at least one of the first and second lead frames includes a plurality of protruding portions disposed on an upper surface thereof.

21. The light emitting device package of claim 20, further comprising a light scattering agent dispersed in the resin portion and including a material having a refractive index greater than a refractive index of a material forming the resin portion.

22. A light emitting device package, comprising:
a package substrate including first and second lead frames;
a light emitting device disposed on the package substrate, including a plurality of light emitting nanostructures; and
a resin portion disposed on the package substrate and sealing the light emitting device,
wherein at least one of the first and second lead frames includes a plurality of protruding portions disposed on an upper surface thereof.

23. The light emitting device package of claim 22, wherein the plurality of protruding portions have at least one of a cone shape and a dome shape.

24. (canceled)

25. (canceled)

26. (canceled)
